(19) United States
(12) Patent Application Publication
(10) Pub. No.: US 2026/0035236 A1
(43) Pub. Date: Feb. 5, 2026

(54) MEMS SENSOR ARRANGEMENT AND METHOD FOR MANUFACTURING A MEMS SENSOR ARRANGEMENT

(71) Applicant: Infineon Technologies AG, Neubiberg (DE)

(72) Inventors: Christian Bretthauer, Muenchen (DE); Steffen Bieselt, Wehlen (DE)

(21) Appl. No.: 19/248,185

(22) Filed: Jun. 24, 2025

(30) Foreign Application Priority Data
Aug. 1, 2024 (DE) 102024122036.8

(51) Int. Cl. B81B 7/02; B81C 1/00

(52) U.S. Cl. CPC B81B 7/02; B81C 1/00341; B81B 2201/0257; B81B 2201/0264; B81B 2203/0127; B81B 2203/0307; B81B 2203/033; B81B 2203/0353; B81B 2203/04; B81B 2207/07; B81C 2201/0105; B81C 2201/0121; B81C 2201/0132; B81C 2201/0174; B81C 2203/019

(57) ABSTRACT

In an embodiment a MEMS sensor arrangement includes a substrate, a pressure sensor structure and a sound transducer structure in a vertically stacked and mechanically coupled configuration, wherein the pressure sensor structure is arranged between the substrate and the sound transducer structure and a through-opening extending through the substrate and the pressure sensor structure and forming a sound-port for the sound transducer structure, wherein the sound transducer structure spans the through-opening, and wherein the pressure sensor structure comprises a pressure sensor element, which is in fluidic connection with the through-opening.

This application claims priority to German Application No. 1020241220356.8, filed on Aug. 1, 2024, which application is hereby incorporated herein by reference.

### TECHNICAL FIELD

Embodiments of the present disclosure relate to a MEMS sensor arrangement and to a method for manufacturing (fabricating) a MEMS sensor arrangement. More specifically, embodiments of the present disclosure relate to a combo MEMS sensor arrangement having a MEMS sound transducer (microphone and/or loudspeaker) and a MEMS pressure sensor, wherein the MEMS pressure sensor comprises a vertical trench pressure cell in the sound-port (through-hole or Bosch cavity) of the combo MEMS sensor arrangement.

### BACKGROUND

The sensing of environmental parameters in the ambient atmosphere, such as sound (acoustic pressure), static pressure, etc., with MEMS-based sensor devices gains more and more importance in the implementation of appropriate sensors within mobile devices, home automation, such as smart-home, and the automotive sector. Sound and pressure detecting structures, e.g., MEMS microphones, barometers, absolute pressure sensors, etc., have found use in smart phones and other portable devices. With the continuous advance and miniaturization of consumer products, the available space in these devices is typically limited.

Therefore, there is a need in the field of sensor devices for consumer applications, e.g., smart phones, to implement an improved sensor arrangement having additional or multiple sensor functionalities without increasing the “bill of materials” (BOM) and the integration space, when compared to a conventional sensor arrangement.

### SUMMARY

According to an embodiment, a MEMS sensor arrangement comprises a substrate, a pressure sensor structure and a sound transducer structure in a vertically stacked and mechanically coupled configuration, wherein the pressure sensor structure is arranged between the substrate and the sound transducer structure, wherein a through-opening extends through the substrate and the pressure sensor structure and forms a sound-port to the sound transducer structure, wherein the sound transducer structure spans the through-opening, and wherein the pressure sensor structure comprises a pressure sensor element, which is in fluidic connection to the through-opening.

According to a further embodiment, a method for manufacturing a MEMS sensor arrangement comprises arranging a substrate, a pressure sensor structure having a pressure sensor element and a sound transducer structure in a vertically stacked and mechanically coupled configuration, wherein the pressure sensor structure is arranged between the substrate and the sound transducer structure, and forming a through-opening through the substrate and the pressure sensor structure and to the sound transducer structure, wherein the sound transducer structure spans the through-opening”.

Thus, according to embodiments of the present disclosure, the MEMS multi-sensor arrangement integrates a pressure sensor structure having a pressure sensor element in the side wall of the through-hole (=sound-port or Bosch cavity) of a MEMS sound transducer structure (MEMS loudspeaker or microphone). According to an embodiment, the pressure sensor element (sensor cell) of the pressure sensor structure may comprise a vertical pressure sensor membrane (lamella).

The specific structure of the MEMS sensor arrangement avoids the need to provide an extra chip area for the additional pressure sensor structure. Avoiding extra chip area for the additional pressure sensor functionality may keep the manufacturing costs low and may provide an increased back-volume for the sound transducer structure resulting in an improved SNR (signal-to-noise-ratio) of the sound transducer.

The MEMS sensor arrangement provides a combo-product that offers the sound transducer (microphone or loudspeaker) and pressure sensor functionality in one package. The MEMS sensor arrangement having the sound transducer structure (microphone or loudspeaker) and the pressure sensor structure are arranged on a single die but can separately connected to read-out devices in order to provide separate sound and pressure read-out options for an ASIC.

As the sound transducer structure and the pressure sensor structure see (are exposed to) the sound pressure variations and the static pressure variations in the sound-port at the same time without any delay, the pressure sensor structure can respond to static pressure changes without a bandwidth limitation.

As the pressure sensor membranes (lamellas) can be arranged, for example, all dielectrically isolated from each other, a high temperature linearity of the resulting pressure sensor structure can be achieved. Moreover, the pressure sensor structure of the MEMS sensor arrangement may be also designed to provide a humidity dependent capacity which can be used to estimate and provide a value for the relative humidity as an additional sensor output signal.

Furthermore, the pressure sensor structure may be specifically implemented to build an integrated environmental barrier through the through opening (sound-port) keeping particle contaminations and (if the perforated barrier layer comprises a hydrophobic surface characteristic) water (or any liquids) to a certain depth away from the pressure sensor structure and sound transducer structure of the MEMS sensor arrangement.

The present concept for a MEMS sensor arrangement having the additional pressure sensor structure can be used with any sound transducer technology, e.g., with a SDM (sealed dual membrane) structure, a SBP (single back plate) structure, a DBP (dual back plate) structure or a piezo-electric sound transducer structure spanning the sound-port.

### BRIEF DESCRIPTION OF THE DRAWINGS

In the following, embodiments of the present disclosure are described in more detail while making reference to the accompanying drawings, in which,

FIG. 1a shows a schematic cross-sectional partial view of a MEMS sensor arrangement in accordance with an embodiment of the present disclosure;

FIG. 1b shows a schematic top (plane) view of the MEMS sensor arrangement (having the sound transducer structure spanning the sound-port) in accordance with an embodiment of the present disclosure;

FIG. 2 shows an enlarged schematic cross-sectional partial view of the MEMS sensor arrangement with an exemplary implementation of the pressure sensor structure in accordance with a further embodiment of the present disclosure;

FIG. 3 shows an enlarged schematic cross-sectional partial view of the MEMS sensor arrangement with an exemplary implementation of the pressure sensor structure in accordance with a further embodiment of the present disclosure;

FIGS. 4a-b show an enlarged schematic partial top (plane) view of the pressure sensor structure and an enlarged schematic cross-sectional partial view of the MEMS sensor arrangement in accordance with a further embodiment of the present disclosure;

FIGS. 5a-b show an enlarged schematic partial top (plane) view of the pressure sensor structure and an enlarged schematic cross-sectional partial view of the MEMS sensor arrangement in accordance with a further embodiment of the present disclosure;

FIG. 6a shows a schematic top (plane) view of the MEMS sensor arrangement through the sound-port and the pressure sensing structure in accordance with an embodiment of the present disclosure;

FIGS. 6b-c show enlarged schematic partial top (plane) views (of a section) of the pressure sensor structure of the MEMS sensor arrangement having a meander-shaped lamella in accordance with a further embodiment of the present disclosure;

FIG. 7 shows an exemplary schematic flow chart of a fabrication method of the MEMS sensor arrangement in accordance with an embodiment of the present disclosure; and

FIG. 8 shows an exemplary schematic flow chart of the fabrication method of the MEMS sensor arrangement wherein a pressure port to the trench element of the trench capacitor is formed through a top isolation layer of the pressure sensor element in accordance with an embodiment of the present disclosure; and

FIG. 9 shows an exemplary schematic flow chart of the fabrication method of the MEMS sensor arrangement wherein a pressure port to the trench element of the trench capacitor is formed through a bottom isolation layer of the pressure sensor element in accordance with an embodiment of the present disclosure.

Before discussing the present embodiments in further detail using the drawings, it is pointed out that in the figures and the specification identical elements and elements having the same functionality and/or the same technical or physical effect are usually provided with the same reference numbers or are identified with the same name, so that the description of these elements and of the functionality thereof as illustrated in the different embodiments are mutually exchangeable or may be applied to one another in the different embodiments.

### DETAILED DESCRIPTION OF ILLUSTRATIVE EMBODIMENTS

In the following description, embodiments are discussed in detail, however, it should be appreciated that the embodiments provide many applicable concepts that can be embodied in a wide variety of the field of MEMS devices, e.g., MEMS sensors or actuators. The specific embodiments discussed are merely illustrative of specific ways to implement and use the present concept, and do not limit the scope of the embodiments. In the following description of embodiments, the same or similar elements or elements that have the same functionality are provided with the same reference sign or are identified with the same name, and a repeated description of elements provided with the same reference number or being identified with the same name is typically omitted. In the following description, a plurality of details is set forth to provide a more thorough explanation of embodiments of the disclosure.

However, it will be apparent to one skilled in the art that other embodiments may be practiced without these specific details. In other instances, well-known structures and devices are shown in block diagram form rather than in detail in order to avoid obscuring examples described herein. In addition, features of the different embodiments described herein may be combined with each other, unless specifically noted otherwise.

It is understood that when an element is referred to as being “connected” or “coupled” to another element, it may be directly connected or coupled to the other element, or intermediate elements may be present. Conversely, when an element is referred to as being “directly” connected to another element, “connected” or “coupled,” there are no intermediate elements. Other terms used to describe the relationship between elements should be construed in a similar fashion (e.g., “between” versus “directly between”, “adjacent” versus “directly adjacent”, and “on” versus “directly on”, etc.).

For facilitating the description of the different embodiments, the figures comprise a Cartesian coordinate system x, y, z, wherein the x-y-plane corresponds, i.e., is parallel, to a first main surface region of a substrate or the (undeflected) surface area of the sound transducer structure (=a reference plane=x-y-plane), wherein the direction vertically up with respect to the reference plane (x-y-plane) corresponds to the “+z” direction, and wherein the direction vertically down with respect to the reference plane (x-y-plane) corresponds to the “−z” direction. In the following description, the term “lateral” means a direction parallel to the x- and/or y-direction, i.e., parallel to the x-y-plane, wherein the term “vertical” means a direction parallel to the z-direction.

In the following description, a thickness of an element usually indicates a vertical dimension of such an element. In the figures, the different elements are not necessarily drawn to scale. Thus, the illustrated dimensions of the different elements may not be necessarily drawn to scale.

In the description of the embodiments, terms and text passages placed in brackets next to a described element or function are to be understood as further explanations, alternative designations, exemplary configurations, exemplary additions and/or exemplary alternatives of the described element or function.

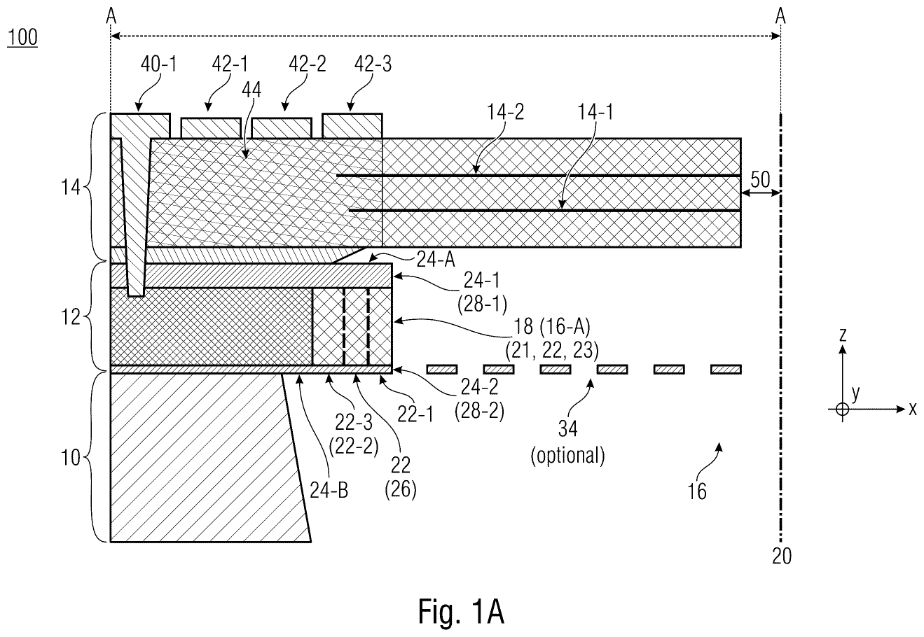

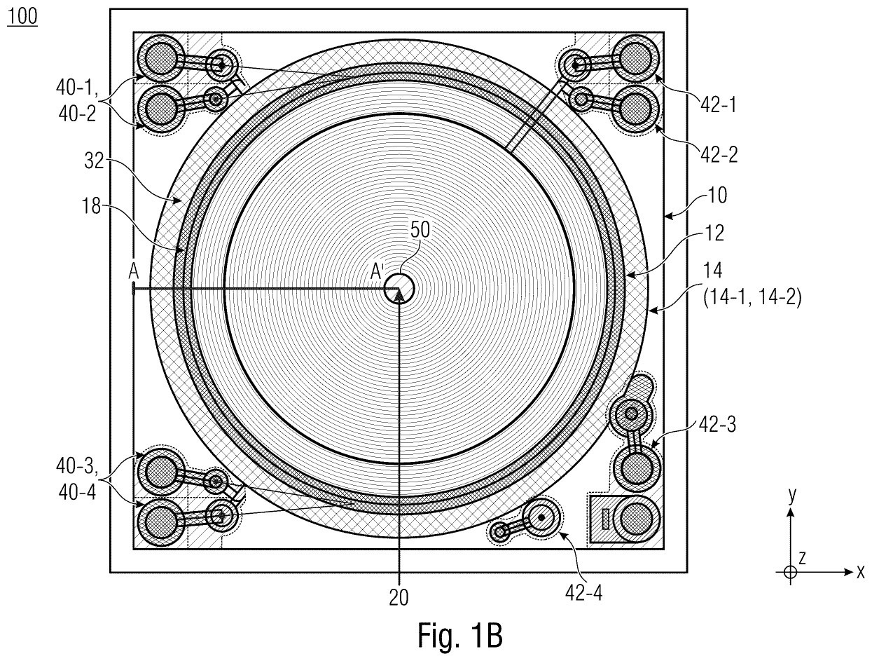

FIG. 1a shows a schematic cross-sectional (partial) view of a MEMS sensor arrangement 100 along a sectional line AA′ (=cross-sectional x-z-plane) of FIG. 1b in accordance with an embodiment of the present disclosure. FIG. 1b shows a schematic top (plane) view of the MEMS sensor arrangement 100 (having a sound transducer structure spanning a sound-port) in accordance with an embodiment of the present disclosure. For facilitating the description of the embodiments, the schematic cross-sectional view of FIG. 1a additionally comprises a schematic representation of different electrical contact elements 40-1, 42-1-42-3, which may be arranged along the sectional line AA′ (=cross-sectional x-z-plane), but not necessarily as exemplarily shown in the schematic plane view of FIG. 1b.

According to an embodiment, the MEMS sensor arrangement 100 comprises a substrate 10, a pressure sensor structure 12 and a sound transducer structure 14 in a vertically stacked and mechanically coupled configuration, wherein the pressure sensor structure 12 is arranged between the substrate 10 and the sound transducer structure 14. A through-opening 16 extends (runs) through the substrate 10 and the pressure sensor structure 12 and forms a sound-port to the sound transducer structure 14. The sound transducer structure 14 spans the through-opening 16. The pressure sensor structure 14 comprises a pressure sensor element 18, which is in fluidic connection to the through-opening 16.

Thus, according to embodiments of the present disclosure, the MEMS sensor arrangement 100 integrates a pressure sensor structure 12 in the side wall of the through-hole 16 (sound-port or Bosch cavity) of the MEMS sound transducer structure 14 (MEMS loudspeaker and/or microphone). The specific structure of the MEMS sensor arrangement 100 does not require an additional footprint (chip area) for the additional pressure sensor structure 12, wherein (when compared to a conventional two sensor arrangement) an improved (increased) back-volume can be provided for the sound transducer structure 14 resulting in an improved SNR (signal-to-noise-ratio) of the sound transducer structure 14, for example.

According to an embodiment, the through-opening 16 may extend e.g. parallel to a vertical center or symmetry axis 20 of the MEMS sensor arrangement 100 and, thus, vertically and centrally through the substrate 10 and the pressure sensor structure 12, to form the sound-port 16 to the sound transducer structure 14. The through-opening 16 may have a diameter between 0.75 mm and 1.5 mm and of about 1 mm±10%. According to an embodiment, the sound transducer structure 14 may at least partially or completely span the through-opening 16. The pressure sensor element 18 of pressure sensor structure 12 may be in an atmospheric pressure connection (fluidic connection) to the through-opening 16 and is thus exposed to the ambient (barometric) pressure of the surrounding atmosphere. The substrate 10 may comprise a semiconductor die, e.g. a silicon die.

According to an embodiment, the pressure sensor element 18 may comprise a sealed sensor cell (vacuum cell) 22, which can be capacitively read out. According to an embodiment, a side wall element 22-1 of the sealed sensor cell 22 may comprise or form a pressure deformable lamella, which outer face is in fluidic connection (atmospheric pressure connection) to the through-opening 16 and, thus, to the ambient atmosphere. A further side wall element 22-3 of the sealed sensor cell 22 may comprise or form a rigid electrode structure, wherein the capacitance C_{SENSE} of the sealed sensor cell (vacuum cell) 22 is formed between the pressure deformable lamella 22-1 and the (laterally opposing) rigid electrode structure 22-3.

According to an embodiment, the pressure deformable lamella 22-1 and the rigid electrode structure 22-3 may be electrically isolated by means of a dielectric material (dielectric layers) 24-1, 24-2 from each other and from further regions, e.g. from electrically conductive or semi-conductive regions, of the pressure sensor structure 12. Upon a deflection ±αx of the pressure deformable lamella 22-1 relative to the rigid electrode structure 22-3, that (lateral) deflection or displacement can be capacitively read-out in order to provide an output signal S_{SENSE} dependent on the deflection (gap change)±Δx.

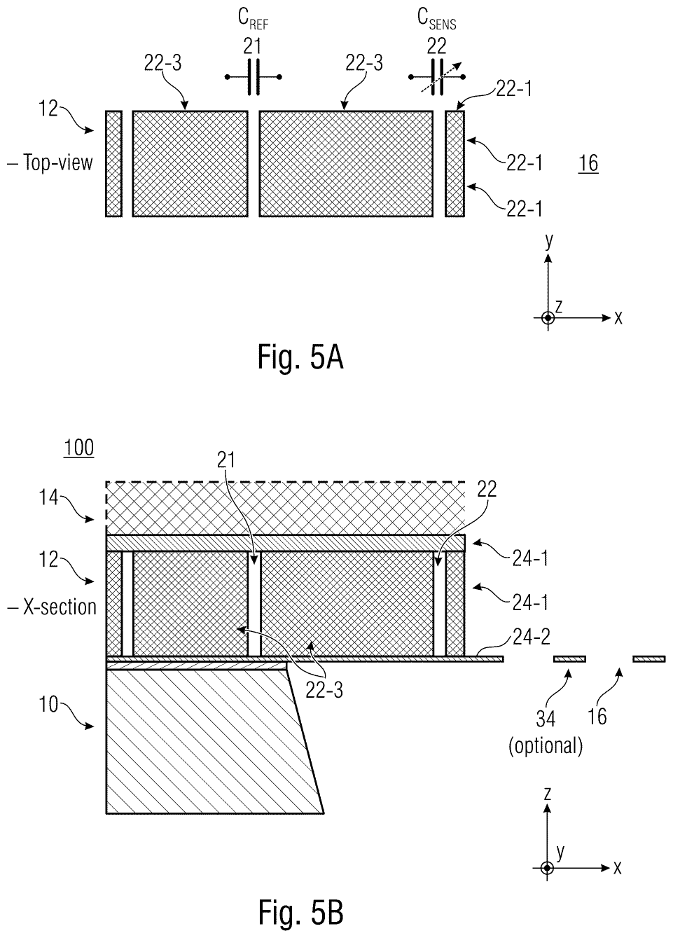

Thus, the pressure deformable lamella 22-1 of the pressure sensor element 18 is integrated (vertically) below the sound transducer structure 14 and may form a portion of the side-wall 16-A of the sound-port 16 (through-hole or Bosch cavity) for the sound transducer structure 12 (see also, for example, FIGS. 5a-b and the associated description).

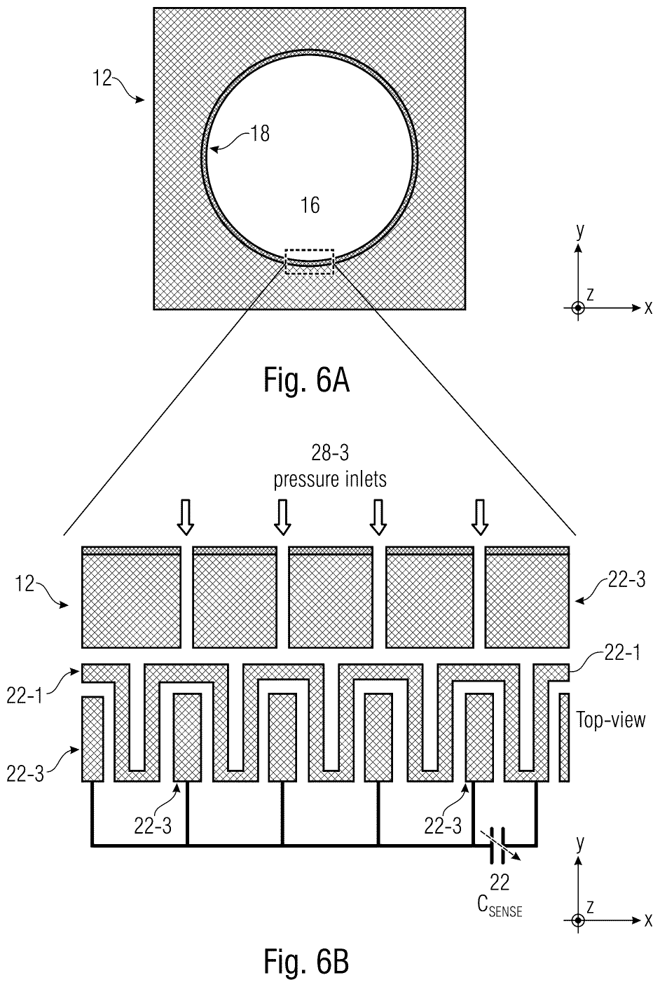

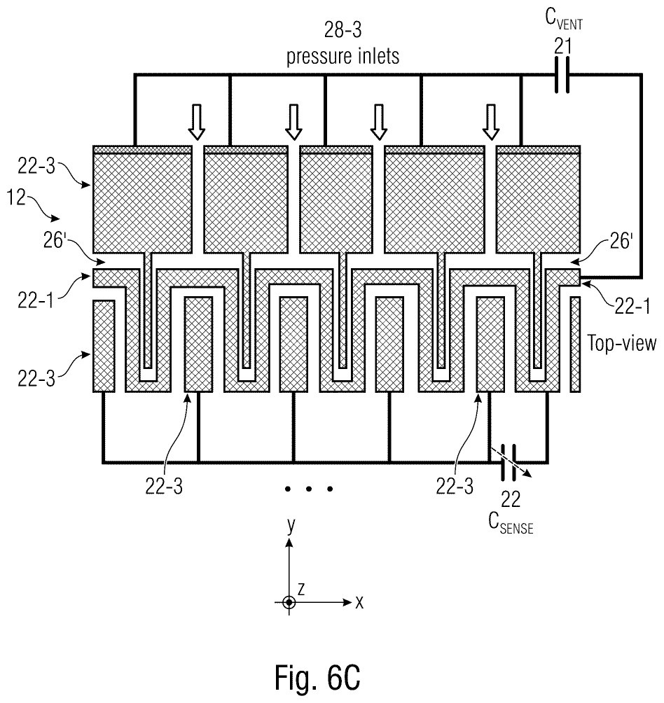

According to an embodiment, the pressure deformable lamella 22-1 of the sealed sensor cell 22 may comprise (in a plane view) a meander-shaped or corrugated structure (shape) at least partially or completely along the perimeter of the through-hole for increasing the capacitance C_{SENSE} of sealed sensor cell 22 (see also FIG. 6 and the associated description, for example).

According to an embodiment, the pressure sensor element 18 may further comprise a further sealed sensor cell (vacuum cell) 21 (C_{REF}), which can be capacitively read out. The further sealed sensor cell (reference capacitor) 21 may be formed between two (opposing) rigid wall elements 22-3, wherein the capacitance C_{REF} of the sealed sensor cell (vacuum cell) 21 can be capacitively read-out in order to provide a reference output signal S_{REF} dependent on the environmental temperature T. The (capacitively effective) side-walls of the further sealed sensor cell (vacuum cell) 21 (C_{REF}) may be electrically isolated by means of the dielectric material (dielectric layers) 24-1, 24-2 from each other and from further regions, e.g. from electrically conductive or semi-conductive regions, of the pressure sensor structure 12.

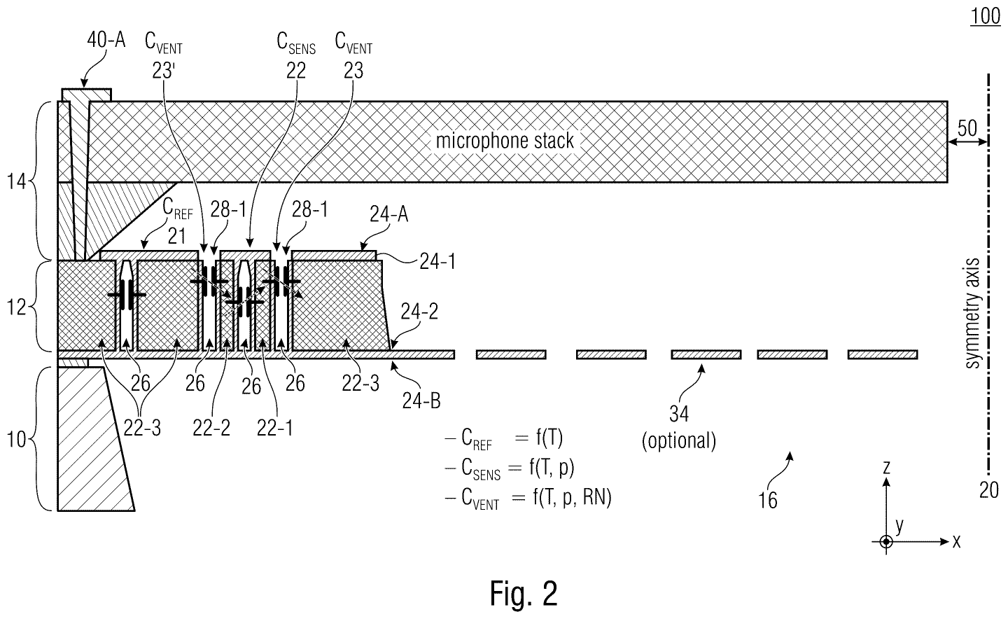

According to a further embodiment (see also FIGS. 2, 3 and 4 and the associated description, for example), a first side wall element 22-1 of the sealed sensor 22 cell may comprise or form a first pressure deformable lamella 22-1, and a second side wall element 22-2 of the sealed sensor cell 22 may comprise or form a second pressure deformable lamella 22-2, wherein (the outer face of) the first and second pressure deformable lamella 22-1, 22-2 are in fluidic connection to the through-opening 16. According to an embodiment, the first and second pressure deformable lamella 22-1, 22-2 may be electrically isolated by means of a dielectric material 24-1, 24-2, e.g. an oxide or a nitride material layer, from each other and from further regions (e.g. from electrically conductive or semi-conductive regions) of the pressure sensor structure 12.

Upon an opposing deflection ±Δx of the first and second pressure deformable lamella 22-1, 22-2 relative to the each other based on a change of the ambient pressure, that (lateral) deflection or displacement can be capacitively read-out (ΔC_{SENSE}) in order to provide an output signal dependent on the deflection (gap change) ±2Δx.

According to a further embodiment, the transduction mechanism for sensing the lamella deflection ±Δx of the respective pressure deformable lamella 22-1, 22-2 may also include a piezoelectric or piezoresistive sensing and read out scheme.

According to an embodiment, the sealed sensor cell(s) 21, 22 may comprise a reduced atmospheric (inner) pressure when compared to the surrounding atmosphere, wherein, for example, the reduced atmospheric pressure in the sealed sensor cell 22 is vacuum or near to vacuum. The sealed sensor cell(s) 21, 22 may be formed as an encapsulation structure or vacuum chamber enclosing a reduced atmospheric pressure when compared to the environmental pressure, wherein, for example, the reduced atmospheric pressure in the low pressure region is vacuum or near to vacuum, e.g., less than about 10% or 1% of the ambient pressure or the standard atmospheric pressure (101.325 kPa) or, for example, less than 50, 20 or less than 5 kPa.

Due to the specific design of the MEMS sensor arrangement 100, it is further possible to independently optimize the MEMS sound transducer structure 14 and the pressure sensor element 18 of the pressure sensor structure 12. Thus, an optimized (best) performance for both sensor devices 12, 14 of the combo sensor, i.e. the pressure sensor structure 12 and the sound transducer structure 14, can be achieved.

In case, the sound transducer structure 14 comprises an SDM structure (SDM=sealed dual membrane), a sealed cavity between two membrane structures is formed as an encapsulation structure or vacuum chamber enclosing a reduced atmospheric pressure when compared to the environmental pressure. Thus, the pressure (e.g. a reduced atmospheric pressure when compared to the surrounding atmosphere, or vacuum, for example) in sealed cavity of the SDM sound transducer structure 14 and in the sealed sensor cell(s) 21, 22 of the pressure sensor element 18 of the pressure sensor structure 12 can be independently optimized so that the best (optimal) performance for both sensor devices 12, 14 can be (relatively) easily and inexpensively achieved.

Moreover, the pressure sensor structure 12 may be arranged to comprise a plurality of pressure sensor elements 22 (C_{SENSE}), 23 (C_{VENT}) and (optionally) reference pressure sensor elements 21 (C_{REF}), wherein the respective pressure sensor elements are electrically isolated by means of a dielectric material from each other and from further regions of the pressure sensor structure. Based on this completely (100%) dielectric isolation an improved TCO (TCO=temperature coefficient of offset) of the pressure sensor structure can be achieved when compared to conventional pressure sensor structures.

According to a further embodiment, the pressure sensor element 18 may comprise a plurality of sealed sensor cells (vacuum cells) 21, 22, which can be separately capacitively read-out. According to an embodiment, the pressure sensor element 18 may comprise, for example, (at least) four electrically separated trench regions to provide (at least) two pressure-dependent capacitive elements 22 and (at least) two reference capacitive elements 21 which can be electrically connected to a Wheatstone bridge.

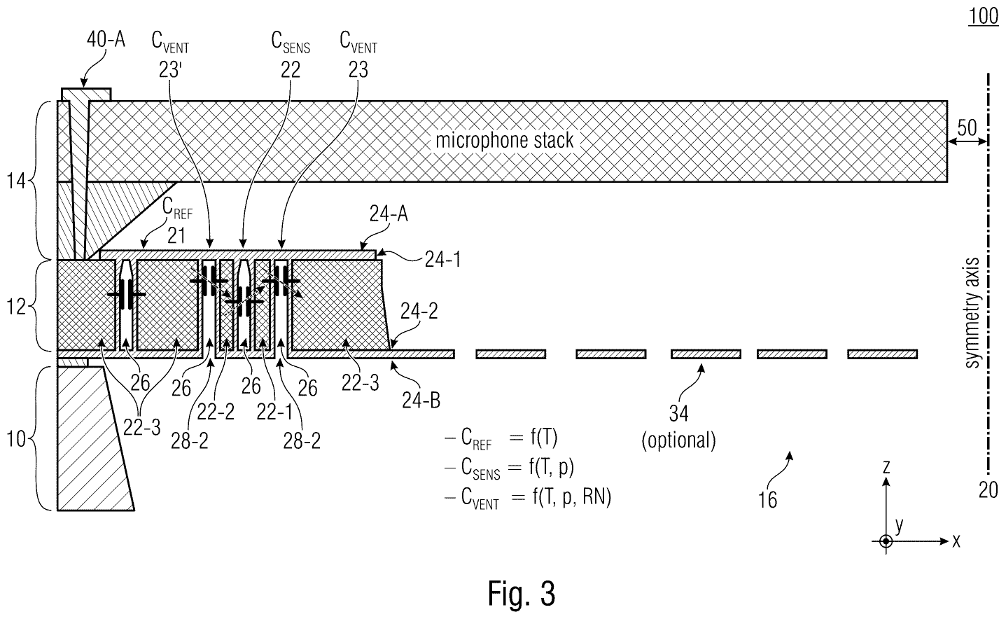

According to an embodiment, the pressure sensor element 18 may comprise a trench capacitor 23 (C_{VENT}) having a (vertical) trench element 26 between the pressure deformable lamella 22-1 or 22-2 and a further side-wall element 22-3 of the pressure sensor element 18, wherein the trench element 26 of the trench capacitor 23 is in fluidic connection (e.g. through a pressure port) to the surrounding atmosphere. According to an embodiment, the trench capacitor 23 may comprise a pressure port 28-1 to the trench element 26 through a top isolation layer 24-1 of the pressure sensor element 18. According to a further embodiment, the trench capacitor 23 may comprise a pressure port 28-2 to the trench elements 23, 23′ through a bottom isolation layer 24-2 of the pressure sensor element 18. (see also, for example, FIGS. 2 and 3 and the associated description)

The trench capacitor element 23 can be capacitively read out, for example. According to an embodiment, the trench capacitor(s) 23 may be also arranged to provide a capacitance C_{VENT} Which comprises (besides a dependency from temperature and pressure) also a dependency from a relative humidity RH of the surrounding atmosphere, i.e. in the though-hole 16. Thus, the capacitance CENT of the trench capacitor(s) 23, which is also indicative for the relative humidity RH of the surrounding atmosphere, can be capacitively read out. Moreover, using a pressure sensor structure 12 having a plurality of trench capacitor elements 23, which comprise a dependency from a relative humidity of the surrounding atmosphere, a humidity sensing functionality may be added too. Thus, the MEMS sensor arrangement 100 may form a combo sensor with a sound transducer, a pressure sensor and a humidity sensor functionality.

According to an embodiment, the pressure sensor element 18 may extend adjacent to a perimeter region 16-A, e.g. along the rim or edge, of the through-opening 16 through the pressure sensor structure 12.

According to an embodiment, the sealed sensor cell(s) 21, 22 and the trench cell(s) 23 may each have a (vertical) trench 26 with a trench depth d₂₆ (vertical dimension) between 15 and 25 μm, or of about 20 μm±2 μm, a trench gap g₂₆ (lateral distance) between 150 to 400 nm or of about 250 nm±50 nm, and a lamella thickness t₂₆ (lateral dimension) between 200 and 400 nm and of about 300 nm±50 nm. According to an embodiment, the pressure sensor structure 12 may have a vertical thickness t₁₂ between 15 and 25 μm, or of about 20 μm±2 μm.

According to an embodiment, a first main surface region 24-A of the pressure sensor structure 12 may form (around the rim or edge of the through-hole) an anchoring region 30 of the sound transducer structure 14 to the pressure sensor structure 12, wherein a second main surface region 24-B of the pressure sensor structure 18 (around the rim or edge of the through-hole) may form an anchoring region 32 of the pressure sensor structure 12 to the substrate 10.

Moreover, mechanically coupling (bonding) the pressure sensor structure 12 between the substrate 10, e.g., a semiconductor substrate such as a silicon substrate (silicon die), and the sound transducer structure 14 may provide an increased mechanical robustness of the MEMS sensor arrangement 100, as the usually present (manufacturing-related) Bosch-roughness of the Bosch cavity (sound-port or through hole) 16 is decoupled from the anchoring region (border region) of the MEMS sound transducer structure 14.

According to an embodiment, the MEMS sensor arrangement 100 may further comprise a perforated barrier layer 34 which extends in parallel to or in the plane of a second (bottom) main surface region 24-B of the pressure sensor structure 12 and through the through-opening 16. The perforated barrier layer 34 may completely span the through-opening 16.

According to an embodiment, the perforated barrier layer 34 may integrally formed with the bottom isolation layer 24-2 of the pressure sensor element 18. The provision of the pressure sensor structure 12 in the sound-port 16 of the sound transducer structure 14 allows to inexpensively implement an environmental barrier 34, e.g., in the form of a perforated barrier layer, which extends through the sound-port 16.

According to an embodiment, the perforated barrier layer (particle protection grid) 34 may comprise a dielectric material, e.g. a nitride material (silicon nitride-SiN) or an oxide material. According to an embodiment, the perforated barrier layer 34 may comprise a hydrophobic dielectric material (a hydrophobic oxide or nitride material) or may comprise at least one of SiN, Al₂O₃, BaTiO₃, or TiO₂, for example. According to an embodiment, the perforated barrier layer 34 may comprise a hydrophobic surface characteristic, e.g. in form of a hydrophobic surface characteristic, surface structure or surface coating.

The dielectric (e.g. SiN) grid 34 spans like a backplate the through-opening 16 acts as an environmental barrier. As the pressure sensor structure 12 may have a vertical thickness t₁₂ between 15 and 25 μm, or of about 20 μm±2 μm, the perforated barrier layer 34 is accordingly spaced from the sound transducer structure 14. Due to this (vertical) space/distance between the perforated barrier layer 34 and the sound transducer structure 14 essentially any squeeze film damping effect between the perforated barrier layer 34 and the sound transducer structure 14 can be avoided. The term “squeeze film damping” or “squeeze film air damping” represents the effect to the opposite force of air on moveable structures, when the air is squeezed or sucked by means of the moveable structure of the sound transducer structure 14.

According to an embodiment, the sound transducer structure 14 may comprise a SDM (sealed dual membrane), SBP (single back-plate), DBP (dual back-plate), or a piezo-electrical sound transducer element. Thus, the present concept for a MEMS sensor arrangement 100 having the additional pressure sensor structure 12 can be used (essentially) with any sound transducer technology, e.g., with a SDM (sealed dual membrane) structure, a SBP (single back-plate) structure, a DBP (dual back-plate) structure or a piezo-electric sound transducer structure spanning the sound-port 16. The list of sound transducer technologies may not be regarded as exhaustive.

With respect to the different embodiments and alternatives of the present disclosure, it should be noted that the sound transducer structure 14 may be formed as a SBP (single backplate) structure, but also as a SDM structure, as a DBP (dual backplate) structure or, in general, a MEMS transducer (sensor or actuator), wherein the MEMS sound transducer structure comprises a deflectable membrane structure 14-1 (vertically spaced from a counter-electrode (back-plate) structure 14-2) in a fluidic connection with the environment and spanning the through-hole 16. According to an embodiment, the membrane structure 14-1 may comprise a circumferential shape in form of a circle, ellipse, oval, square, rectangle, hexagon, or any regular convex polygon, for example. The terms “electrode” and “structure” are intended to illustrate that the membrane structure(s) 14-1 and the rigid electrode structure 14-2 can respectively comprise a semi-conductive or conductive layer or, also, a layer sequence or layer stack having a plurality of different layers, wherein at least one of the layers is electrically conductive, e.g., comprises a metallization layer and/or a conductive semiconductor (e.g., poly-silicon) layer.

As exemplarily shown in FIGS. 1a-b, the MEMS sensor arrangement 100 may further comprise electrical contact elements 40- #(e.g. 40-1, 40-2, . . . ) and 42- #(42-1, 42-2, . . . ) for providing an electrical connection between the MEMS sensor arrangement 100 having the pressure sensor structure 12 and the sound transducer structure 14 and further electric components or circuits, e.g. an ASIC (ASIC=application specific integrated circuit) or a further processing device.

The sound transducer structure 14 may comprise an isolation structure 44, which is provided for fixing the peripheral portions of the sound transducer structure 14, such as the membrane structure(s) 14-1 and the rigid electrode structure 14-2. The electrical contact elements 40- #(e.g. 40-1, 40-2, . . . , 40-4) and 42- #(e.g. 42-1, 42-2, . . . , 42-4) may be arranged as vias in the isolation structure 44 and/or as contact pads on the isolation structure 44. The insulation structure 44 may comprise a dielectric material, for example, a SiO₂ material based on a tetraethyl orthosilicate (TEOS) deposition process.

FIG. 1b shows a schematic top (plane) view of the MEMS sensor arrangement 100 (having a sound transducer structure 14 spanning a sound-port and the pressure sensing structure 14) in accordance with an embodiment of the present disclosure.

As shown in the exemplary plan view of FIG. 1b, the MEMS sensor arrangement 100 may comprise the electrical contact elements 40- #(e.g. 40-1, 40-2, . . . ) and 42- #(42-1, 42-2, . . . ) for providing an electrical connection to further electric components or circuits, e.g. an ASIC (ASIC=application specific integrated circuit).

As further shown in FIG. 1b, the membrane structure 14-1 of the sound transducer structure 14 may comprise a ventilation hole 50, e.g. in a geometrical center region of the sound transducer structure 14. The ventilation hole 50 may be provided for further defining the ventilation characteristics through the membrane structure 14-1. The diameter d₅₀ of the ventilation hole 50 may be dimensioned to provide a low pass characteristic of the ventilation hole 50 for pressure changes in the environment. Thus, slow ambient changes (e.g. slow atmospheric pressure changes) can be ventilated through the ventilation opening 50, wherein faster pressure changes (e.g. acoustic sound pressure changes in the environment) do not pass the ventilation opening 50 but deflect the membrane structure 14-1 of the sound transducer structure 14 and can be detected.

The MEMS sensor arrangement 100 may be a functional part of a portable electronic device. The portable electronic device may be, for example, any consumer application, e.g., a smart phone, a smart watch, a tablet, a PC, or any electronic device, using the sound transducer structure 14 of the MEMS sensor arrangement 100 for sensing or outputting an acoustic sound and using the pressure sensor structure 12 of the MEMS sensor arrangement 100 for sensing the barometric pressure p, temperature T and/or relative humidity RH in the ambient atmosphere by providing the output signal(s) S_{SENSE}, S_{REF}, S_{VENT}.

Before describing further embodiments, it should be noticed that in the present description of embodiments, same or similar elements having the same structure and/or function are provided with the same reference numbers or the same name, wherein a detailed description of such elements will not be repeated for every embodiment. Thus, the above description with respect to FIGS. 1a-b is equally applicable to the further embodiments as described below. In the following description, different implementations of the embodiments of FIGS. 1a-b and, essentially, the differences, e.g. additional elements and/or structures, and the technical effect(s) resulting therefrom are discussed in detail.

FIG. 2 shows an enlarged schematic cross-sectional partial view of the MEMS sensor arrangement 100 with an exemplary implementation of the pressure sensor structure 12 having the pressure sensor element 18 in accordance with a further embodiment of the present disclosure.

The MEMS sensor arrangement 100 comprises the substrate 10, the pressure sensor structure 12 and the sound transducer structure 14 in a vertically stacked and mechanically coupled configuration, wherein the pressure sensor structure 12 is arranged between the substrate 10 and the sound transducer structure 14. The through-opening 16 through the substrate 10 and the pressure sensor structure 12 forms a sound-port to the sound transducer structure 14, which spans the through-opening 16.

As exemplarily shown in FIG. 2, the pressure sensor element 18 comprises the sealed sensor cells (vacuum cells) 21 (C_{REF}) and 22 (C_{SENSE}) and the (open) trench capacitors 23, 23′ (C_{VENT}), which can be capacitively read out.

The sealed sensor cell (reference capacitor C_{REF}) 21 is formed between two (opposing) rigid wall elements 22-3, wherein the capacitance C_{REF} of the sealed sensor cell (vacuum cell) 21 can be capacitively read-out in order to provide a reference output signal S_{REF} dependent on the environmental temperature T, C_{REF}=f (T). According to an embodiment, the sealed sensor cell 21 may comprise a reduced atmospheric (inner) pressure when compared to the surrounding atmosphere.

The sealed sensor cell (sense capacitor C_{SENSE}) 22 comprises a first side wall element 22-1 having (forming) a first pressure deformable lamella, and a second side wall element 22-2 having (forming) a second pressure deformable lamella, wherein the outer face of the first and second pressure deformable lamella 22-1, 22-2 are in fluidic connection to the through-opening 16. The capacitance C_{SENSE} of the sealed sensor cell (vacuum cell) 22 can be capacitively read-out in order to provide a sense output signal dependent on the environmental temperature T and the ambient pressure p, C_{SENSE}=f (T, p). Upon a deflection ±Δx of the first and second pressure deformable lamella 22-1, 22-2 (opposite to each other), that (lateral) deflection or displacement of the lamellas 22-1, 22-2 can be capacitively read-out in order to provide the output signal S_{SENSE} dependent on the deflection (=gap change ±2Δx).

According to an embodiment, the pressure sensor element 18 may comprise a first trench capacitor (vent capacitor C_{VENT}) 23 having a trench element 26 between the pressure deformable lamella 22-1 and a further (rigid) side wall element 22-3 of the pressure sensor element 18 and a second trench capacitor (vent capacitor C′_{VENT}) 23′ having a further trench element 26 between the pressure deformable lamella 22-2 and a further rigid side wall element 22-3 of the pressure sensor element 18. The trench elements 26 of the first and second trench capacitor 23, 23′ are in fluidic connection to the surrounding atmosphere.

The capacitance C_{VENT} of the first and second trench capacitor 23, 23′ can be capacitively read-out in order to provide a (vent) output signal S_{VENT} dependent on the environmental temperature, the ambient pressure p and the relative humidity RH of the surrounding atmosphere, C_{VENT}=f (T, p, RH). Upon a deflection ±Δx of the pressure deformable lamella 22-1 relative to the rigid electrode structure 22-3 and a deflection ±Δx of the pressure deformable lamella 22-2 relative to the rigid electrode structure 22-3, these (lateral) deflections or displacements can be capacitively readout in order to provide an output signal dependent on the deflection (gap change) ±Δx of the first trench capacitor 23 and of the second trench capacitor 23′, respectively.

Based on a ambient pressure change ±Δp, the capacitance change ΔC_{SENSE} (and, thus, the output signal S_{SENSE}) of the sealed sensor cell (sense capacitor) 22 and the capacitance change ΔC_{VENT} (and, thus, the output signal S_{VENT}) of the trench capacitors 23, 23′ have opposite signs. The output signal S_{SENSE} and output signal S_{VENT} form differential sensor signals, which can be differentially read-out.

However, the capacitance C_{VENT} of the trench capacitors 23, 23′ is also sensitive to the relative humidity RH of the ambient atmosphere humidity. This RH contribution as well as the influence of temperature T can be compensated by an evaluation of the read-out capacitance values C_{VENT} against the capacitance of the reference capacitor C_{REF} which is only temperature dependent.

According to the embodiment of FIG. 2, the trench capacitors (C_{VENT}) 23, 23′ may each comprise a pressure port 28-1 to the trench elements 26 through the top isolation layer 24-1 of the pressure sensor element 18. As exemplarily shown in FIG. 2, the bottom isolation layer 24-2 of the pressure sensor element 18 may close the bottom side of the trench elements 26 of the trench capacitors (C_{VENT}) 23, 23′.

According to an embodiment, the side walls (capacitor plates) of the reference capacitor(s) 21 (C_{REF}), the sense capacitor(s) 22 (C_{SENSE}) and the trench capacitor(s) 23 (C_{VENT}) may each be electrically isolated by means of a dielectric material 24-1, 24-2, e.g. an oxide or a nitride material, from each other and from further regions (e.g. from electrically conductive or semi-conductive regions) of the pressure sensor structure 12.

According to an embodiment, the reference capacitor(s) 21 (C_{REF}), the sense capacitor(s) 22 (C_{SENSE}) and the trench capacitor 23 (C_{VENT}) may each have a trench 26 with a trench depth dr (vertical dimension) between 15 and 25 μm, or of about 20 μm±2 μm, a trench gap gr (lateral distance) between 150 to 400 nm or of about 250 nm±50 nm, and a lamella thickness tr (lateral dimension) between 200 and 400 nm and of about 300 nm±50 nm.

According to an embodiment, the pressure sensor element 18 may comprise a plurality of reference capacitor(s) 21 (C_{REF}), sense capacitor(s) 22 (C_{SENSE}) and trench capacitor(s) 23 (C_{VENT}), which can be separately capacitively read out and can be electrically connected to a Wheatstone bridge.

According to an embodiment, the pressure sensor element 18 may extend adjacent to a perimeter region 16-A, e.g. along the rim or edge, of the through-opening 16 through the pressure sensor structure 12.

As exemplarily shown in FIG. 2, the MEMS sensor arrangement 100 may further (optionally) comprise the perforated barrier layer 34 which extends in parallel to or in the plane of a second (bottom) main surface region 24-B of the pressure sensor structure 12 and through the through-opening 16. The perforated barrier layer 34 may completely span the through-opening 16. The perforated barrier layer 34 may integrally formed with the bottom isolation layer 24-2 of the pressure sensor element 18, for example. According to an embodiment, the perforated barrier layer 34 may comprise a hydrophobic dielectric material

FIG. 3 shows an enlarged schematic cross-sectional partial view of the MEMS sensor arrangement 100 with an exemplary implementation of the pressure sensor structure 12 in accordance with a further embodiment of the present disclosure.

According to the embodiment of FIG. 3, the MEMS sensor arrangement 100 differs from the MEMS sensor arrangement 100 of FIG. 2 in that the trench capacitors (C_{VENT}) 23 may comprise a pressure port 28-2 to the trench elements 23, 23′ through a bottom isolation layer 24-1 of the pressure sensor element 18.

According to the embodiment of FIG. 3, the trench capacitors (C_{VENT}) 23, 23′ may comprise the pressure port 28-2 to the trench elements 26 through the bottom isolation layer 24-2 of the pressure sensor element 18. As exemplarily shown in FIG. 3, the top isolation layer 24-1 of the pressure sensor element 18 may close the top side of the trench elements 26 of the trench capacitors (C_{VENT}) 23, 23′. According to an embodiment, the side walls (capacitor plates) of the reference capacitor(s) 21 (C_{REF}), the sense capacitor(s) 22 (C_{SENSE}) and the trench capacitor(s) 23 (C_{VENT}) may each be electrically isolated by means of the dielectric material 24-1, 24-2, e.g. an oxide or a nitride material, from each other and from further regions (e.g. from electrically conductive or semi-conductive regions) of the pressure sensor structure 12.

According to a further embodiment (in form of a combination of the embodiments of FIGS. 2 and 3), the trench capacitors (C_{VENT}) 23, 23′ may comprise the pressure port 28-1 to the trench elements 26 through the top isolation layer 24-1 and, also, the further pressure port 28-2 to the trench elements 26 through the bottom isolation layer 24-2 of the pressure sensor element 18. Thus, the trench elements 26 may be fluidically accessible from the top and bottom.

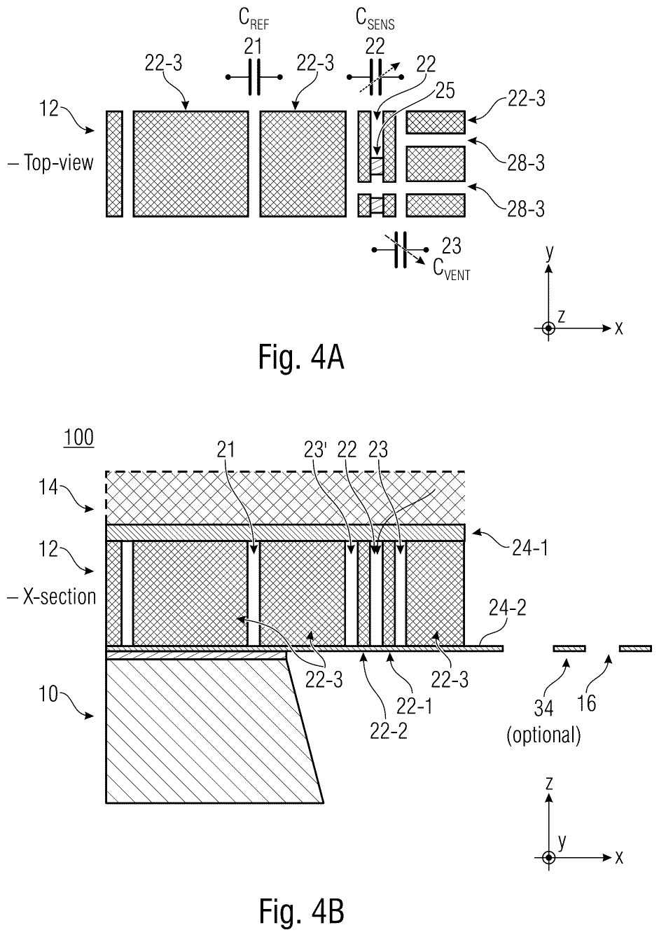

FIGS. 4a-b show an enlarged schematic partial top (plane) view of the pressure sensor structure 12 and an enlarged schematic cross-sectional partial view of the MEMS sensor arrangement 100 with an exemplary implementation of the pressure sensor structure 12 in accordance with a further embodiment of the present disclosure.

As exemplarily shown in FIGS. 4a-b, the first side wall element 22-1 of the sealed sensor cell 22 comprises or forms the first pressure deformable lamella 22-1, and the second side wall element 22-2 of the sealed sensor cell 22 comprises or forms the second pressure deformable lamella 22-2, wherein (the outer face of) the first and second pressure deformable lamella 22-1, 22-2 are in fluidic connection to the through-opening 16. Lateral barrier elements (plugs) 25 having an insulating material, e.g. a dielectric (oxide and/or nitride) material, are arranged in the trench element 26 if the sealed sensor cell 22 to hermetically close the sealed sensor cell 22. According to an embodiment, the first and second pressure deformable lamella 22-1, 22-2 may be electrically isolated by means of a dielectric material 24-1, 24-2, e.g. an oxide or a nitride material layer, from each other and from further regions (e.g. from electrically conductive or semi-conductive regions) of the pressure sensor structure 12.

According to the embodiment of FIGS. 4a-b, the pressure sensor structure 12 of the MEMS sensor arrangement 100 differs from the MEMS sensor arrangement 100 of FIGS. 2 and 3 in that the pressure sensor structure 12 may comprise a (lateral) pressure port (channels) 28-3 to the trench elements 26 of the trench capacitors (C_{VENT}) 23, 23′ laterally through a rigid wall element 22-3 of the pressure sensor element 18.

Thus, the pressure port (channels) 28-3 to the trench elements 23, 23′ may run laterally through the rigid wall element 22-3 of the pressure sensor element 18 so that the trench capacitors (C_{VENT}) 23, 23′ are in fluidic connection to the through-opening 16. The rigid wall element 22-3 may extend adjacent to a perimeter region 16-A, e.g. along the rim or edge, of the through-opening 16.

According to an embodiment, the pressure sensor element 18 further comprises the further sealed sensor cell (vacuum cell) 21 (C_{REF}), which can be capacitively read out. The further sealed sensor cell (reference capacitor) 21 is formed between two (opposing) rigid wall elements 22-3, wherein the capacitance C_{REF} of the sealed sensor cell (vacuum cell) 21 can be capacitively read-out in order to provide a reference output signal S_{REF} dependent on the environmental temperature. The (capacitively active) side-walls of the further sealed sensor cell (vacuum cell) 21 (C_{REF}) may be electrically isolated by means of the dielectric material (dielectric layers) 24-1, 24-2 from each other and from further regions, e.g. from electrically conductive or semi-conductive regions, of the pressure sensor structure 12.

FIGS. 5a-b show an enlarged schematic partial top (plane) view of the pressure sensor structure 12 and an enlarged schematic cross-sectional partial view of the MEMS sensor arrangement 100 with an exemplary implementation of the pressure sensor structure 12 in accordance with a further embodiment of the present disclosure.

According to an embodiment, the pressure sensor element 18 may comprise a sealed sensor cell (vacuum cell C_{SENSE}) 22, which can be capacitively read out. The side wall element 22-1 of the sealed sensor cell 22 comprises or forms the pressure deformable lamella, which outer face is in fluidic connection (atmospheric pressure connection) to the through-opening 16 and, thus, to the ambient atmosphere. A further side wall element 22-3 of the sealed sensor cell 22 comprises or forms a rigid electrode structure, wherein the capacitance C_{SENSE} of the sealed sensor cell (vacuum cell) 22 is formed between the pressure deformable lamella 22-1 and the (laterally opposing) rigid electrode structure 22-3.

According to an embodiment, the pressure deformable lamella 22-1 and the rigid electrode structure 22-3 may be electrically isolated by means of a dielectric material (dielectric layers) 24-1, 24-2 from each other and from further regions, e.g. from electrically conductive or semi-conductive regions, of the pressure sensor structure 12. Upon a deflection ±Δx of the pressure deformable lamella 22-1 relative to the rigid electrode structure 22-3, that (lateral) deflection or displacement can be capacitively read-out in order to provide an output signal S_{SENSE} dependent on the deflection (gap change) ±Δx.

Thus, the pressure deformable lamella 22-1 of the pressure sensor element 18 is integrated (vertically) below the sound transducer structure 14 and may form a portion of the side-wall 16-A of the sound-port 16 (through-hole or Bosch cavity) of the sound transducer structure 14. According to an embodiment, the pressure sensor element 18 may extend adjacent to a perimeter region 16-A, e.g. along the rim or edge, of the through-opening 16 through the pressure sensor structure 12.

FIG. 6a shows a schematic top (plane) view of the MEMS sensor arrangement 100 through the sound-port 16 and the pressure sensing structure 12 in accordance with an embodiment of the present disclosure. FIGS. 6b-c show enlarged schematic partial top (plane) views (of a section) of the pressure sensor structure 12 of the MEMS sensor arrangement 100 with an exemplary implementation of the pressure sensor structure 12 having (in a plane view) a meander-shaped lamella in accordance with a further embodiment of the present disclosure.

As exemplarily shown in FIGS. 6b-c, the pressure port (channels) 28-3 to the trench elements 26 may run laterally through the rigid wall element 22-3 of the pressure sensor element 18 so that (the outer face of) the meander-shaped or corrugated pressure deformable lamella 22-1 is in fluidic connection to the through-opening 16. The rigid wall element 22-3 may extend adjacent to a perimeter region, e.g. along the rim or edge, of the through-opening 16.

As exemplarily shown in FIGS. 6b-c, the pressure sensor element 18 comprises the sealed sensor cell (vacuum cell C_{SENSE}) 22, which can be capacitively read out. The side wall element 22-1 of the sealed sensor cell 22 comprises or forms the pressure deformable lamella, which outer face is in fluidic connection (atmospheric pressure connection) to the through-opening 16 and, thus, to the ambient atmosphere. A further side wall element 22-3 of the sealed sensor cell 22 comprises or forms a rigid electrode structure, wherein the capacitance C_{SENSE} of the sealed sensor cell (vacuum cell) 22 is formed between the pressure deformable lamella 22-1 and the (laterally opposing) rigid electrode structure 22-3.

As exemplarily shown in FIG. 6c, the pressure sensor element 18 may comprise a trench capacitor 23 (C_{VENT}) having a (vertical) trench element 26′ between opposing sections of the meander-shaped or corrugated pressure deformable lamella 22-1, wherein the trench element 26′ of the trench capacitor 23 is in fluidic connection (through the pressure port 28-3) to the surrounding atmosphere. The trench capacitor element (C_{VENT}) 23 can be capacitively read out, for example.

According to an embodiment, the pressure deformable lamella 22-1 of the sealed sensor cell 22 may comprise (in a plane view) a meander-shaped or corrugated structure (shape) at least partially or completely along the perimeter of the through-hole. The meander-shaped or corrugated wall section of the pressure deformable lamella 22-1 may have a curved, round, sinusoidal, square, rectangular, triangle or saw-tooth shape at least partially along the perimeter of the through-hole. Increasing the effective length. Thus, the effective pressure sensing area of the pressure deformable lamella 22-1 and, consequently, the capacity and sensitivity of the sealed sensor cell 22 of the pressure sensor structure 12 can be increased.

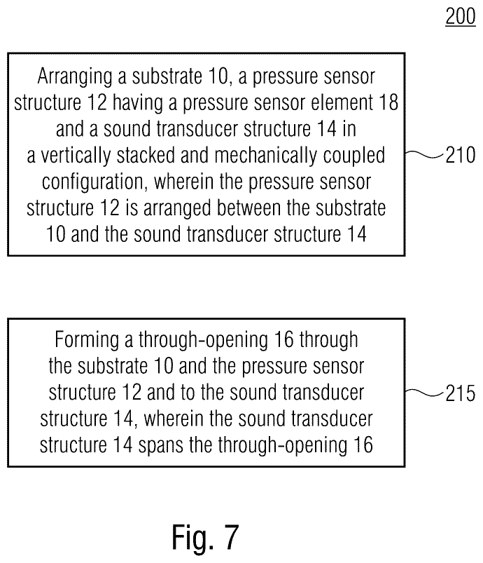

FIG. 7 shows an exemplary schematic flow chart of a fabrication method 200 of the MEMS sensor arrangement 100 in accordance with an embodiment of the present disclosure.

According to an embodiment, the method 200 for manufacturing a MEMS sensor arrangement 100 comprises the step of arranging 210 a substrate 10, a pressure sensor structure 12 having a pressure sensor element 18 and a sound transducer structure 14 in a vertically stacked and mechanically coupled configuration, wherein the pressure sensor structure 12 is arranged between the substrate 10 and the sound transducer structure 14, and the step of forming 215 a through-opening 16 through the substrate 10 and the pressure sensor structure 12 and to the sound transducer structure 14, wherein the sound transducer structure 14 spans the through-opening 16.

According to an embodiment, the (manufacturing) step of arranging 210 the pressure sensor structure further comprises a step of forming 220 a sealed sensor cell 22 by forming 222 a pressure deformable lamella 22-1 in a side wall element of the sealed sensor cell 22, which is in fluidic connection connected to the through-opening 16, and the step of electrically isolating 224 the pressure deformable lamella 22-1 by means of a dielectric material from further regions of the pressure sensor structure 22.

According to an embodiment, the step of arranging 210 the pressure sensor structure further comprises a step of forming 225 a sealed sensor cell 22 by forming 227 a first pressure deformable lamella 22-1 in a first side wall element of the sealed sensor cell 22, and a second pressure deformable lamella 22-2 in a second side wall element of the sealed sensor cell 22, wherein the first and second pressure deformable lamellas 22-1, 22-2 are in fluidic connection to the through-opening 16, and the step of electrically isolating 229 the first and second pressure deformable lamella 22-1, 22-2 by means of a dielectric material 24-1, 24-2 from further regions of the pressure sensor structure 12.

According to an embodiment, the step of arranging 210 the pressure sensor structure further comprises a step of forming 230 a trench capacitor 23 having a trench element 26 between the pressure deformable lamella 22-1 and a further side wall element 22-3 of the pressure sensor element 23, wherein the trench element 26 of the trench capacitor 23 is in fluidic connection to the surrounding atmosphere.

According to an embodiment, the manufacturing method 100 further comprises a step of forming 240 a pressure port 28-1 to the trench element 26 of the trench capacitor 23 through a top isolation layer 24-1 of the pressure sensor element 18.

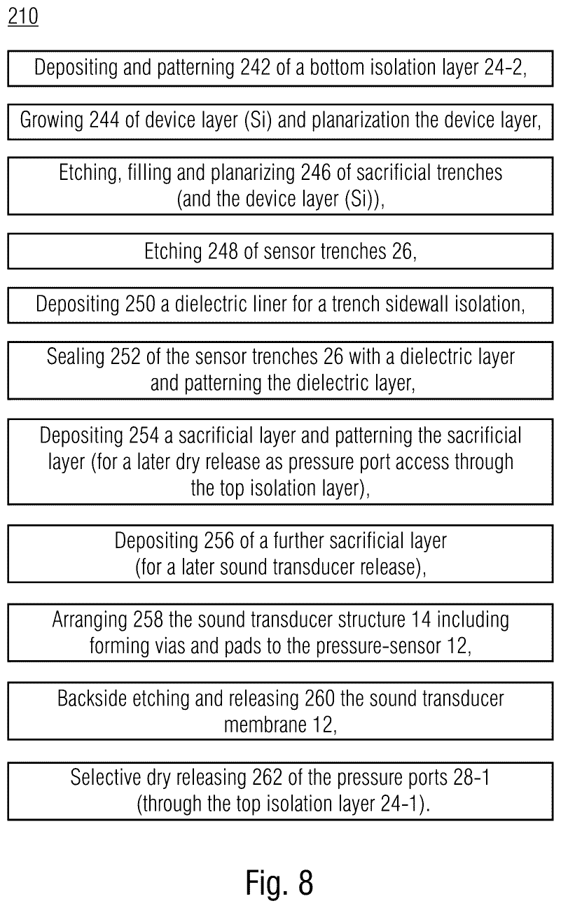

FIG. 8 shows an exemplary schematic flow chart of the different (partial) steps of arranging 210 the pressure sensor structure of the fabrication method 200 of the MEMS sensor arrangement wherein a top pressure port 28-1 to the trench element 26 of the trench capacitor 23 is formed through a top isolation layer 24-1 of the pressure sensor element 18.

According to the fabrication method 200 of FIG. 8, the pressure sensor element 18, as exemplarily shown in FIG. 2, may be formed which comprises the sealed sensor cells (vacuum cells) 21 (C_{REF}) and 22 (C_{SENSE}) and the (open) trench capacitors 23, 23′ (C_{VENT}), which can be capacitively read out. The trench capacitors (C_{VENT}) 23, 23′ may comprise a pressure port 28-1 to the trench elements 26 through a top isolation layer 24-1 of the pressure sensor element 18. The bottom isolation layer 24-2 of the pressure sensor element 18 may close the bottom side of the trench elements 26 of the trench capacitors (C_{VENT}) 23, 23′.

According to an embodiment, the step of arranging 210 the pressure sensor structure further comprises the steps of
depositing and patterning 242 of a bottom isolation layer 24-2,
growing 244 of device layer (Si) and planarization the device layer,
etching, filling and planarizing 246 of sacrificial trenches (and the device layer (Si)),
etching 248 of sensor trenches 26,
depositing 250 a dielectric liner for a trench sidewall isolation,
sealing 252 of the sensor trenches 26 with a dielectric layer and patterning the dielectric layer,
depositing 254 a sacrificial layer and patterning the sacrificial layer (for a later dry release as pressure port access through the top isolation layer),
depositing 256 of a further sacrificial layer (for a later sound transducer release),
arranging 258 the sound transducer structure 14 including forming vias and pads to the pressure-sensor 12,
backside etching and releasing 260 the sound transducer membrane 12, and
selective dry releasing 262 of the pressure ports 28-1 (through the top isolation layer 24-1).

According to an embodiment, the manufacturing method 100 further comprises a step of forming 270 a pressure port 28-1 to the trench element 26 of the trench capacitor 23 through a bottom isolation layer 24-2 of the pressure sensor element 18.

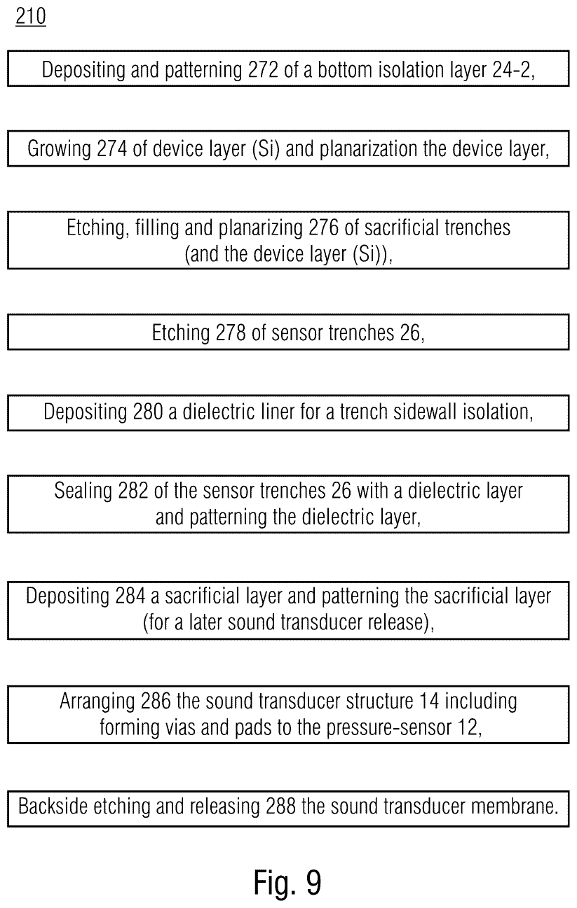

FIG. 9 shows an exemplary schematic flow chart of the different (partial) steps of arranging 210 the pressure sensor structure of the fabrication method 200 of the MEMS sensor arrangement wherein a bottom pressure port 28-2 to the trench element 26 of the trench capacitor 23 is formed through a bottom isolation layer 24-2 of the pressure sensor element 18.

According to the fabrication method 200 of FIG. 9, the pressure sensor element 18, as exemplarily shown in FIG. 3, may be formed which comprises the sealed sensor cells (vacuum cells) 21 (C_{REF}) and 22 (C_{SENSE}) and the (open) trench capacitors 23, 23′ (C_{VENT}), which can be capacitively read out. The trench capacitors (C_{VENT}) 23, 23′ may comprise a pressure port 28-2 to the trench elements 26 through a bottom isolation layer 24-2 of the pressure sensor element 18. The top isolation layer 24-2 of the pressure sensor element 18 may close the bottom side of the trench elements 26 of the trench capacitors (C_{VENT}) 23, 23′.

According to an embodiment, the step of arranging 210 the pressure sensor structure further comprises the steps of
depositing and patterning 272 of a bottom isolation layer 24-2,
growing 274 of device layer (Si) and planarization the device layer,
etching, filling and planarizing 276 of sacrificial trenches (and the device layer (Si)),
etching 278 of sensor trenches 26,
depositing 280 a dielectric liner for a trench sidewall isolation,
sealing 282 of the sensor trenches 26 with a dielectric layer and patterning the dielectric layer,
depositing 284 a sacrificial layer and patterning the sacrificial layer (for a later sound transducer release),
arranging 286 the sound transducer structure 14 including forming vias and pads to the pressure-sensor 12, and
backside etching and releasing 288 the sound transducer membrane.

According to an embodiment, the manufacturing method 200 may further comprise a step of arranging 290 the pressure sensor element 18 adjacent to a perimeter region of the through opening.

According to an embodiment, the manufacturing method 200 may further comprise a step of forming 292 a perforated barrier layer 34 in parallel to or in the plane of the second main surface region 24-B of the pressure sensor structure 12 and through the through-opening 16. According to an embodiment, the perforated barrier layer 34 may comprise a hydrophobic dielectric material (e.g. a hydrophobic oxide material, e.g. Al₂O₃, BaTiO₃, or TiO₂, or a hydrophobic nitride material, e.g., silicon nitride (SiN).

According to an embodiment, the manufacturing method 200 may further comprise a step of providing 294 a hydrophobic surface characteristic on the perforated barrier layer 34, e.g. forming a hydrophobic coating on the perforated barrier layer.

To summarize, the present disclosure describes a MEMS sensor arrangement and a method for manufacturing such a MEMS sensor arrangement. According to a technical implementation, the MEMS sensor arrangement 100 comprises a MEMS sound transducer structure 14 and a pressure sensor structure 12 on a substrate 10, e.g., on a single silicon die, wherein the pressure sensor structure 12 is integrated below the sound transducer structure 14 along the side wall of the sound-port 16 (through-hole or Bosch cavity) of the sound transducer structure 14. In other words, a vertical capacitive pressure cell structure 18 is placed below a MEMS sound transducer structure 14 (MEMS microphone and/or loudspeaker structure) in its sound-port 16 (Bosch cavity) to enable an improved and cost/area optimized combo-sensor arrangement 100 (a combination of multiple sensor structures).

The MEMS sensor arrangement 10 provides a combo-product that offers the sound transducer 14 (microphone or loudspeaker) and pressure sensor 12 functionality in one package. The MEMS sensor arrangement 100 having the sound transducer structure 14 (microphone or loudspeaker) and the pressure sensor structure 12 are arranged on a single die 10 but can separately connected to read-out devices in order to separate sound and pressure read-out on an ASIC. Thus, the protocols to interface the sound transducer structure 14 (microphone or loudspeaker) and the pressure sensor structure 12 may maintained unchanged.

The MEMS sensor arrangement (the combo sensor system) 100 functionally provides a “parallel connection” of the sound transducer structure 14 and the pressure sensor structure 12 in accordance with the described embodiments. The sound transducer structure 14 measures a sound pressure level (SPL) and the pressure sensor structure 12 measure an ambient pressure P_{ambient}. In this configuration, the sound transducer structure 14 and the pressure sensor structure 12 see (are exposed to) the sound pressure variations and the static pressure variations in the sound-port 16 at the same time without any delay therebetween and without a bandwidth limitation (LFRO) of the pressure sensor structure 12.

Low Frequency Roll Off (LFRO) refers to the gradual decrease in the amplitude of low frequency signals (e.g. static pressure variations) as they pass from the sound-port 16 through the sound transducer structure 14 (which acts a low-pass filter) to the back-volume of the sound transducer structure 14.

According to the present disclosure, the pressure sensor structure 12 may comprise different specific implementation options for the pressure sensor element(s), such as for the position(s) of the pressure inlet(s) and for the design of the pressure sensing element 18. Consequently, the pressure sensor membranes (lamellas) 22-1, 22-2 can be arranged, for example, all dielectrically isolated by/from each other, which can provide an improved temperature linearity of the resulting pressure sensor structure. Moreover, the pressure sensor structure 12 of the MEMS sensor arrangement 100 may be also designed to provide a capacitor (trench capacitor C_{VENT}) 23, wherein its capacitance C_{VENT} is also dependent on the relative humidity (RH) of the surrounding atmosphere so that its humidity dependent capacity can be used (read out) to estimate and provide a value for the relative humidity as an additional sensor output signal S_{VENT}. Thus, the (read-out) sensor output signal S_{VENT} of the capacitance C_{VENT} of the trench capacitor 23 may provide a dependency or value of the relative humidity of the surrounding atmosphere. Thus, the MEMS sensor arrangement 100 may provide a combo sensor with a sound transducer, a pressure sensor and a humidity sensor functionality.

Furthermore, the pressure sensor structure 12 may be specifically implemented to build an integrated environmental barrier 34 through the through-opening 16 (sound-port) keeping particle contaminations and (if the perforated barrier layer comprises a hydrophobic surface characteristic) water (or any liquids) to a certain depth away from the pressure sensor structure 12 and sound transducer structure 14 of the MEMS sensor arrangement 100. Specifically, this environmental barrier 34 can comprise a hydrophobic material or can be coated hydrophobically in order to protect the sound transducer structure from water entering through the sound-port and reaching the sound transducer structure

Additional embodiments and aspects are described which may be used alone or in combination with the features and functionalities described herein.

According to an embodiment, a MEMS sensor arrangement comprises a substrate, a pressure sensor structure and a sound transducer structure in a vertically stacked and mechanically coupled configuration, wherein the pressure sensor structure is arranged between the substrate and the sound transducer structure, wherein a through-opening extends through the substrate and the pressure sensor structure and forms a sound-port to the sound transducer structure, wherein the sound transducer structure spans the through-opening, and
wherein the pressure sensor structure comprises a pressure sensor element, which is in fluidic connection to the through-opening.

According to an embodiment, the pressure sensor element comprises a sealed sensor cell, which can be capacitively read out.

According to an embodiment, a side wall element of the sealed sensor cell comprises a pressure deformable lamella, which is in fluidic connection to the through-opening.

According to an embodiment, the pressure deformable lamella is electrically isolated by means of a dielectric material from further regions of the pressure sensor structure.

According to an embodiment, the pressure deformable lamella of the sealed sensor cell comprises a meander-shaped structure.

According to an embodiment, a first side wall element of the sealed sensor cell comprises a first pressure deformable lamella, and a second side wall element of the sealed sensor cell comprises a second pressure deformable lamella, wherein the first and second pressure deformable lamella are in fluidic connection to the through-opening.

According to an embodiment, the first and second pressure deformable lamella are electrically isolated by means of a dielectric material from further regions of the pressure sensor structure.

According to an embodiment, the sealed sensor cell has a trench with a trench depth between 15 and 25 μm, or of about 20 μm±2 μm, a trench gap between 150 to 400 nm or of about 250 nm±50 nm, and a lamella thickness between 200 and 400 nm and of about 300 nm ±50 nm.

According to an embodiment, the sealed sensor cell comprises a reduced atmospheric pressure when compared to the surrounding atmosphere.

According to an embodiment, the pressure sensor element comprises a plurality of sealed sensor cells, which can be separately capacitively read out.

According to an embodiment, the pressure sensor element further comprises a trench capacitor having a trench element between the pressure deformable lamella and a further side wall element of the pressure sensor element, wherein the trench element of the trench capacitor is in fluidic connection to the surrounding atmosphere.

According to an embodiment, the trench capacitor comprises a pressure port to the trench element through a top isolation layer of the pressure sensor element.

According to an embodiment, the trench capacitor comprises a pressure port to the trench element through a bottom isolation layer of the pressure sensor element.

According to an embodiment, wherein a sensor output signal S_{VENT} of the capacitance C_{VENT} of the trench capacitor provides a value of a relative humidity of the surrounding atmosphere, and wherein the MEMS sensor arrangement provides a combo sensor with a sound transducer, a pressure sensor and a humidity sensor functionality.

According to an embodiment, the pressure sensor element extends adjacent to a perimeter region of the through opening.

According to an embodiment, a first main surface region of the pressure sensor structure forms an anchoring region of the sound transducer structure to the pressure sensor structure, wherein a second main surface region of the pressure sensor structure forms an anchoring region of the pressure sensor structure to the substrate.

According to an embodiment, the pressure sensor structure has a vertical thickness between 15 and 25 μm, or of about 20 μm±2 μm.

According to an embodiment, the MEMS sensor arrangement further comprises a perforated barrier layer which extends in parallel to or in the plane of a second main surface region of the pressure sensor structure and through the through-opening.

According to an embodiment, the perforated barrier layer comprises a nitride material, e.g., silicon nitride (SiN).

According to an embodiment, the perforated barrier layer comprises a hydrophobic surface characteristic.

According to an embodiment, the sound transducer structure comprises a SDM (sealed dual membrane), SBP (single back-plate), DBP (dual back-plate), or a piezo-electrical sound transducer element.

According to an embodiment, the substrate comprises a silicon die.

According to an embodiment, a method for manufacturing a MEMS sensor arrangement comprises (—) arranging a substrate, a pressure sensor structure having a pressure sensor element and a sound transducer structure in a vertically stacked and mechanically coupled configuration, wherein the pressure sensor structure is arranged between the substrate and the sound transducer structure, and (—) forming a through-opening through the substrate and the pressure sensor structure and to the sound transducer structure, wherein the sound transducer structure spans the through-opening.

According to an embodiment, arranging the pressure sensor structure further comprises: forming a sealed sensor cell by forming a pressure deformable lamella in a side wall element of the sealed sensor cell, which is in fluidic connection connected to the through-opening, and by electrically isolating the pressure deformable lamella by means of a dielectric material from further regions of the pressure sensor structure.

According to an embodiment, arranging the pressure sensor structure further comprises: forming a sealed sensor cell by forming a first pressure deformable lamella in a first side wall element of the sealed sensor cell, and a second pressure deformable lamella in a second side wall element of the sealed sensor cell, wherein the first and second pressure deformable lamellas are in fluidic connection to the through-opening, and by electrically isolating the first and second pressure deformable lamella by means of a dielectric material from further regions of the pressure sensor structure.

According to an embodiment, arranging the pressure sensor structure further comprises: forming a trench capacitor having a trench element between the pressure deformable lamella and a further side wall element of the pressure sensor element, wherein the trench element of the trench capacitor is in fluidic connection to the surrounding atmosphere.

According to an embodiment, the method further comprises forming a pressure port to the trench element of the trench capacitor through a top isolation layer of the pressure sensor element.

According to an embodiment, arranging the pressure sensor structure further comprises:
depositing and patterning of a bottom isolation layer,
growing of device layer (Si) and planarization the device layer,
etching, filling and planarizing of sacrificial trenches (and the device layer (Si)), etching of sensor trenches,
depositing a dielectric liner for a trench sidewall isolation,
sealing of the sensor trenches with a dielectric layer and patterning the dielectric layer, depositing a sacrificial layer and patterning the sacrificial layer (for a later dry release
as pressure port access through the top isolation layer),
depositing of a further sacrificial layer (for a later sound transducer release),
arranging the sound transducer structure including forming vias and pads to the pressure-sensor,
backside etching and releasing the sound transducer membrane, and
selective dry releasing of the pressure ports (through the top isolation layer).

According to an embodiment, the method further comprises forming a pressure port to the trench element of the trench capacitor through a bottom isolation layer of the pressure sensor element.

According to an embodiment, arranging the pressure sensor structure further comprises:
depositing and patterning of a bottom isolation layer,
growing of device layer (Si) and planarization the device layer,
etching, filling and planarizing of sacrificial trenches (and the device layer (Si)),
etching of sensor trenches,
depositing a dielectric liner for a trench sidewall isolation,
sealing of the sensor trenches with a dielectric layer and patterning the dielectric layer,
depositing a sacrificial layer and patterning the sacrificial layer (for a later sound transducer release),
arranging the sound transducer structure including forming vias and pads to the pressure-sensor, and
backside etching and releasing the sound transducer membrane.

According to an embodiment, the method further comprises arranging the pressure sensor element adjacent to a perimeter region of the through opening.

According to an embodiment, the method further comprises: forming a perforated barrier layer in parallel to or in the plane of the second main surface region of the pressure sensor structure and through the through-opening.

According to an embodiment, the perforated barrier layer comprises a hydrophobic dielectric material.

According to an embodiment, the method further comprises: providing a hydrophobic surface characteristic on the perforated barrier layer.

Although some aspects have been described as features in the context of an apparatus, it is clear that such a description may also be regarded as a description of corresponding features of a method. Although some aspects have been described as features in the context of a method, it is clear that such a description may also be regarded as a description of corresponding features concerning the functionality of an apparatus.

Depending on certain implementation requirements, embodiments of the control circuitry can be implemented in hardware or in software or at least partially in hardware or at least partially in software. Generally, embodiments of the control circuitry can be implemented as a computer program product with a program code, the program code being operative for performing one of the methods when the computer program product runs on a computer. The program code may, for example, be stored on a machine-readable carrier.

In the foregoing detailed description, it can be seen that various features are grouped together in examples for the purpose of streamlining the disclosure. This method of disclosure is not to be interpreted as reflecting an intention that the claimed examples require more features than are expressly recited in each claim. Rather, as the following claims reflect, subject matter may lie in less than all features of a single disclosed example. Thus, the following claims are hereby incorporated into the detailed description, where each claim may stand on its own as a separate example. While each claim may stand on its own as a separate example, it is to be noted that, although a dependent claim may refer in the claims to a specific combination with one or more other claims, other examples may also include a combination of the dependent claim with the subject matter of each other dependent claim or a combination of each feature with other dependent or independent claims. Such combinations are proposed herein unless it is stated that a specific combination is not intended. Furthermore, it is intended to include also features of a claim to any other independent claim even if this claim is not directly made dependent to the independent claim.

Although specific embodiments have been illustrated and described herein, it will be appreciated by those of ordinary skill in the art that a variety of alternate and/or equivalent implementations may be substituted for the specific embodiments shown and described without departing from the scope of the present embodiments. This application is intended to cover any adaptations or variations of the specific embodiments discussed herein. Therefore, it is intended that the embodiments be limited only by the claims and the equivalents thereof.

What is claimed is:

1. A MEMS sensor arrangement comprising:
a substrate, a pressure sensor structure and a sound transducer structure in a vertically stacked and mechanically coupled configuration,
wherein the pressure sensor structure is arranged between the substrate and the sound transducer structure; and
a through-opening extending through the substrate and the pressure sensor structure and forming a sound-port for the sound transducer structure,
wherein the sound transducer structure spans the through-opening, and
wherein the pressure sensor structure comprises a pressure sensor element, which is in fluidic connection with the through-opening.

2. The MEMS sensor arrangement of claim 1, wherein the pressure sensor element comprises a sealed sensor cell configured to capacitively read out.

3. The MEMS sensor arrangement of claim 2, wherein a side wall element of the sealed sensor cell comprises a pressure deformable lamella, which is in fluidic connection with the through-opening.

4. The MEMS sensor arrangement of claim 3, wherein the pressure deformable lamella is electrically isolated by a dielectric material from further regions of the pressure sensor structure.

5. The MEMS sensor arrangement of claim 3, wherein the pressure deformable lamella of the sealed sensor cell comprises a meander-shaped structure.

6. The MEMS sensor arrangement of claim 2, wherein a first side wall element of the sealed sensor cell comprises a first pressure deformable lamella, and a second side wall element of the sealed sensor cell comprises a second pressure deformable lamella, and wherein the first and second pressure deformable lamella are in fluidic connection with the through-opening.

7. The MEMS sensor arrangement of claim 6, wherein the first and second pressure deformable lamella are electrically isolated by a dielectric material from further regions of the pressure sensor structure.

8. The MEMS sensor arrangement of claim 2, wherein the sealed sensor cell has a trench with a trench depth between 15 and 25 μm, or of about 20 μm±2 μm, a trench gap between 150 to 400 nm or of about 250 nm±50 nm, and a lamella thickness between 200 and 400 nm and of about 300 nm±50 nm.

9. The MEMS sensor arrangement of claim 2, wherein the sealed sensor cell comprises a reduced atmospheric pressure compared to a surrounding atmosphere.

10. The MEMS sensor arrangement of claim 1, wherein the pressure sensor element comprises a plurality of sealed sensor cells configured to separately capacitively read out.

11. The MEMS sensor arrangement of claim 3, wherein the pressure sensor element further comprises a trench capacitor having a trench element between the pressure deformable lamella and a further side wall element, and wherein the trench element of the trench capacitor is in fluidic connection with a surrounding atmosphere.

12. The MEMS sensor arrangement of claim 11, wherein the trench capacitor comprises a pressure port to the trench element through a top isolation layer of the pressure sensor element.

13. The MEMS sensor arrangement of claim 11, wherein the trench capacitor comprises a pressure port to the trench element through a bottom isolation layer of the pressure sensor element.

14. The MEMS sensor arrangement of claim 11, wherein the trench capacitor is configured to provide a sensor output signal of a capacitance of the trench capacitor that comprises a value of a relative humidity of the surrounding atmosphere, and
wherein the MEMS sensor arrangement is a combo sensor with a sound transducer, a pressure sensor and a humidity sensor functionality.

15. The MEMS sensor arrangement of claim 1, wherein the pressure sensor element extends adjacent to a perimeter region of the through-opening.

16. The MEMS sensor arrangement of any of claim 1,
wherein a first main surface region of the pressure sensor structure forms an anchoring region of the sound transducer structure to the pressure sensor structure, and
wherein a second main surface region of the pressure sensor structure forms an anchoring region of the pressure sensor structure to the substrate.

17. The MEMS sensor arrangement of claim 1, wherein the pressure sensor structure has a vertical thickness between 15 and 25 μm, or of about 20 μm±2 μm.

18. The MEMS sensor arrangement of claim 1, further comprising:
a perforated barrier layer, which extends in parallel to or in a plane of a second main surface region of the pressure sensor structure and through the through-opening.

19. The MEMS sensor arrangement of claim 18, wherein the perforated barrier layer comprises a nitride material.

20. The MEMS sensor arrangement of claim 18, wherein the perforated barrier layer comprises a hydrophobic surface characteristic.

21. The MEMS sensor arrangement of claim 1, wherein the sound transducer structure comprises a SDM (sealed dual membrane), a SBP (single back-plate), a DBP (dual back-plate), or a piezo-electrical sound transducer element.

22. The MEMS sensor arrangement of claim 1, wherein the substrate comprises a silicon die.
